(19) United States
(12) Patent Application Publication
(10) Pub. No.: US 2023/0335550 A1
(43) Pub. Date: Oct. 19, 2023

(54) MONOLITHIC 3D INTEGRATED CIRCUIT AND MANUFACTURING METHOD THEREOF

(71) Applicant: AJO UNIVERSITY INSDUSTRY-ACADEMIC COOPERATION FOUNDATION, Suwon-si (KR)

(72) Inventor: Junseok HEO, Suwon-si (KR)

(73) Assignee: AJO UNIVERSITY INSDUSTRY-ACADEMIC COOPERATION FOUNDATION, Suwon-si (KR)

(21) Appl. No.: 18/033,132

(22) PCT Filed: Aug. 18, 2021
(86) PCT No.: PCT/KR2021/010943

§ 371 Date: Apr. 21, 2023

(30) Foreign Application Priority Data
May 28, 2021 (KR) 10-2021-0069226

(51) Int. Cl. H01L 29/24; H01L 29/76; H01L 21/02; H01L 29/66; H01L 27/06; H01L 21/8258

(52) U.S. Cl. CPC H01L 27/0688; H01L 21/02568; H01L 21/8258; H01L 29/24; H01L 29/66969; H01L 29/7606

(57) ABSTRACT

Disclosed is a monolithic 3D integrated circuit including a semiconductor substrate, a first semiconductor device formed on the semiconductor substrate, a dielectric layer covering the semiconductor substrate and the first semiconductor device, a wiring structure formed in the dielectric layer, and a second semiconductor device formed on the dielectric layer and including a seed layer including a 2D semiconductor material and a crystallized semiconductor layer on the seed layer.

### TECHNICAL FIELD

The present disclosure relates to a monolithic three-dimensional integrated circuit and a manufacturing method thereof.

### BACKGROUND ART

The semiconductor manufacturing industry continues to strive to improve processing capability and power consumption of integrated circuits (ICs). Traditionally, this has been achieved by reducing the minimum feature size. However, in recent years, it has become difficult to continue reducing the minimum feature size due to process limitations. Accordingly, the technique of stacking a plurality of device layers into a three-dimensional (3D) IC has emerged as an approach to improve processing capability and power consumption of ICs.

3D IC technology includes multilithic technology that independently completes a Front-End-Of-Line (FEOL) process (or previous process) for each stacked object, then integrates them and electrically connects them to each other through a through-silicon via, and monolithic technology that sequentially forms a plurality of stacked objects directly on a single semiconductor substrate (e.g., a wafer).

In the case of multilithic technology, there is an advantage that there is no process restriction because a semiconductor process of each layer is independently performed, but there are disadvantages such as low vertical wiring density and limitations in thinning due to wafer bonding. For this reason, research and investment in the monolithic technology capable of realizing an ideal vertical wiring density, reducing the length of wiring, and enabling thinning by using a thin interlayer dielectric (ILD) layer are being actively conducted.

However, the monolithic technology has limitations due to high-temperature process conditions required in a process of forming devices and wiring structures on a single wafer and then stacking and forming other devices thereon. For example, as upper devices are formed under high-temperature process conditions, characteristics and reliability of lower devices such as a high-performance silicon CMOS are degraded. Furthermore, there are also limitations on materials that can be used as interconnection metal wires and degradation of properties.

As an alternative, a method of using a crystalline silicon-based semiconductor or a low-temperature oxide semiconductor as a semiconductor material capable of upper stack integration at a low temperature has been proposed. However, because such a method is accompanied by performance degradation due to limitations in charge mobility, the fundamental goals of high performance and energy efficiency improvement to be achieved through a 3D IC cannot be achieved.

### DESCRIPTION OF EMBODIMENTS

### Technical Problem

The present disclosure provides a 3D integrated circuit and a manufacturing method thereof capable of overcoming limitations of monolithic technology by forming and integrating high-mobility semiconductor devices with materials that can be used under a low thermal budget and may overcome the limit of charge transfer characteristics of crystalline silicon.

The inventive concept of the disclosure is not limited to the above objectives, but other objectives not described herein may be clearly understood by those of ordinary skilled in the art from descriptions below.

### Solution to Problem

According to an aspect of the disclosure, there is provided a monolithic three-dimensional (3D) integrated circuit, the monolithic 3D integrated circuit includes: a semiconductor substrate; a first semiconductor device formed on the semiconductor substrate; a dielectric layer configured to cover the semiconductor substrate and the first semiconductor device; a wiring structure formed in the dielectric layer; and a second semiconductor device formed on the dielectric layer and including a seed layer including a two-dimensional (2D) semiconductor material and a crystallized semiconductor layer on the seed layer.

According to an exemplary embodiment, the 2D semiconductor material may include at least one of a metal chalcogenide-based material, a carbon-containing material, and an oxide semiconductor material.

According to an exemplary embodiment, the semiconductor layer may include a semiconductor material having higher charge mobility than that of a semiconductor material constituting the semiconductor substrate.

According to an exemplary embodiment, the semiconductor layer may include at least one of germanium, a compound semiconductor material containing the germanium, and a chalcogen material.

According to an exemplary embodiment, the semiconductor substrate may include silicon.

According to another aspect of the disclosure, there is provided a method of manufacturing a monolithic 3D integrated circuit, the method includes: forming a first semiconductor device on a semiconductor substrate; forming a dielectric layer covering the semiconductor substrate and the first semiconductor device and a wiring structure in the dielectric layer; forming a seed structure including a 2D semiconductor material on the dielectric layer; and forming a crystallized semiconductor layer on the seed structure.

According to an exemplary embodiment, the forming of the seed structure may include: transferring the seed structure formed on the growth substrate onto the dielectric layer or directly forming the seed structure on the dielectric layer.

According to an exemplary embodiment, the seed structure may include a plurality of island-like structures including the 2D semiconductor material or has a film shape including the 2D semiconductor material.

According to an exemplary embodiment, the 2D semiconductor material may include at least one of a metal chalcogenide-based material, a carbon-containing material, and an oxide semiconductor material.

According to an exemplary embodiment, the crystallized semiconductor layer may include a semiconductor material having higher charge mobility than that of a semiconductor material constituting the semiconductor substrate.

According to an exemplary embodiment, the crystallized semiconductor layer may include at least one of germanium, a compound semiconductor material containing the germanium, and a chalcogen material.

According to an exemplary embodiment, the forming of the crystallized semiconductor layer may be performed through heat treatment at a temperature of 450° C. or less.

According to an exemplary embodiment, the semiconductor substrate may include silicon.

### Advantageous Effects of Disclosure

According to embodiments of the inventive concept, after a Back-End-of-Line (BEOL) process (or a post process), a monolithic 3D integrated circuit may be implemented by forming a semiconductor device with a high mobility channel material including a 2D semiconductor material and a crystalline semiconductor material (e.g., germanium (Ge)) on a dielectric layer in a low temperature environment.

Accordingly, performance may be improved by preventing deterioration in characteristics and reliability of lower high-performance semiconductor devices, interconnection metal wires, etc. of a monolithic 3D integrated circuit, problems such as an increase in RC delay time and an increase in power consumption may be improved through simplification and miniaturization of a wiring structure, and integration may be improved.

In addition, because there is no need to introduce expensive extreme ultraviolet (EUV) equipment for an ultra-miniaturization process required for a monolithic 3D integrated circuit, manufacturing costs may be greatly reduced.

Effects obtainable by embodiments of the inventive concept are not limited to the effects described above, and other effects not described herein may be clearly understood by one of ordinary skill in the art to which the present disclosure belongs from the following description.

### BRIEF DESCRIPTION OF DRAWINGS

A brief description of each drawing is provided to more fully understand drawings recited in the present disclosure.

FIG. 1 is a cross-sectional view of some embodiments of a monolithic three-dimensional integrated circuit according to an exemplary embodiment of the present disclosure.

FIG. 2 is a cross-sectional view of some more detailed embodiments of the monolithic three-dimensional integrated circuit of FIG. 1.

FIGS. 3 and 4 to 10 are views for explaining a method of manufacturing a monolithic 3D integrated circuit according to an exemplary embodiment of the present disclosure.

### MODE OF DISCLOSURE

Embodiments according to the inventive concept are provided to more completely explain the inventive concept to one of ordinary skill in the art, and the following embodiments may be modified in various other forms and the scope of the inventive concept is not limited to the following embodiments. Rather, these embodiments are provided so that the present disclosure will be thorough and complete, and will fully convey the scope of the present disclosure to one of ordinary skill in the art.

It will be understood that, although the terms first, second, etc. may be used herein to describe various members, regions, layers, sections, and/or components, these members, regions, layers, sections, and/or components should not be limited by these terms. These terms do not denote any order, quantity, or importance, but rather are only used to distinguish one component, region, layer, and/or section from another component, region, layer, and/or section. Thus, a first member, component, region, layer, or section discussed below could be termed a second member, component, region, layer, or section without departing from the teachings of embodiments. For example, as long as within the scope of this disclosure, a first component may be named as a second component, and a second component may be named as a first component.

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

When a certain embodiment may be implemented differently, a specific process order may be performed differently from the described order. For example, two consecutively described processes may be performed substantially at the same time or performed in an order opposite to the described order.

In the drawings, variations from the illustrated shapes may be expected because of, for example, manufacturing techniques and/or tolerances. Thus, embodiments of the inventive concept should not be construed as being limited to the particular shapes of regions illustrated herein but may include deviations in shapes that result, for example, from manufacturing processes. Like reference numerals in the drawings denote like elements, and thus their overlapped explanations are omitted.

As used herein, the term “and/or” includes any and all combinations of one or more of the associated listed items.

Hereinafter, embodiments of the inventive concept will be described in detail with reference to the accompanying drawings.

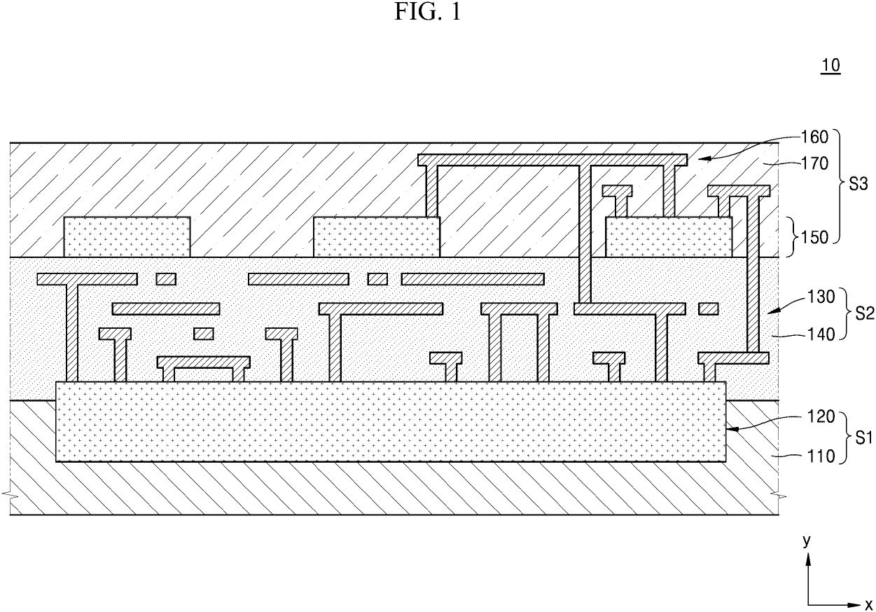

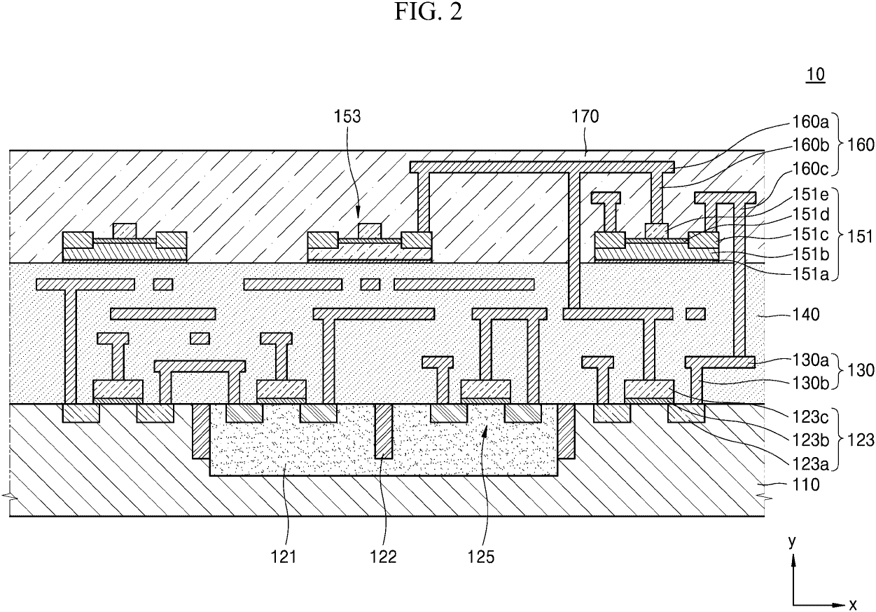

FIG. 1 is a cross-sectional view of some embodiments of a monolithic three-dimensional (3D) integrated circuit 10 according to an exemplary embodiment of the present disclosure, and FIG. 2 is a cross-sectional view showing some more detailed embodiments of the monolithic 3D integrated circuit 10 of FIG. 1, illustratively showing an embodiment in which CMOS devices are integrated on top and bottom.

Referring to FIGS. 1 and 2, the monolithic 3D integrated circuit 10 includes a FEOL structure S1 (hereinafter referred to as a first structure), a BEOL structure (hereinafter referred to as a second structure) on the first structure S1, and a stack structure S3 (hereinafter referred to as the third structure) on the second structure S2.

The first structure S1 may include a semiconductor substrate 110 and a first device unit 120.

The semiconductor substrate 110 may be a silicon substrate. On the other hand, the semiconductor substrate 110 may be one of a silicon germanium substrate, a germanium substrate, a SiGe-on-insulator (SGOI), a silicon-on-insulator (SOI), and a germanium-on-insulator (GOI). Alternatively, the semiconductor substrate 110 may include a semiconductor material such as indium antimonide, a lead tellurium compound, indium arsenide, indium phosphide, gallium arsenide, or gallium antimonide. The semiconductor substrate 110 may include a conductive area, for example, a well doped with impurities, or a structure doped with impurities, and may also have various device isolation structures such as a shallow trench isolation (STI) structure (see FIG. 2).

The first device unit 120 may be on and inside the semiconductor substrate 110.

The first device unit 120 may include a plurality of first semiconductor devices such as a transistor, a memory cell, a pixel sensor, other types of semiconductor devices, or a combination thereof.

Describing an embodiment of the first device unit 120 shown in FIG. 2 in more detail, the first device unit 120 may include a complementary metal oxide semiconductor (CMOS) device formed on the semiconductor substrate 110 such that an NMOS transistor 123 and a PMOS transistor 125 operate complementarily.

The CMOS device may include an N-type well 121 formed in the semiconductor substrate 110 including P-type silicon, a PMOS transistor 125 formed in an active area in the N-type well 121 defined by device isolation layers 122, and an NMOS transistor 123 formed in an active area other than the N-type well 121.

The NMOS transistor 123 may include a source/drain area 123a doped with high concentration N impurities in the semiconductor substrate 110, and a gate dielectric layer 123b and a gate electrode 123c sequentially formed on the semiconductor substrate 110 between source/drain areas 123a. The PMOS transistor 125 may have a configuration corresponding to the NMOS transistor 123.

The second structure S2 may include a first wiring structure 130 for electrically connecting the first semiconductor devices of the first device unit 120 to each other, and a first dielectric layer 140 for covering the semiconductor substrate 110 and the first device unit 120 and insulating the first wiring structure 130.

The first wiring structure 130 may include a wiring layer 130a extending in a horizontal direction (x direction), and a contact plug 130b that connects the wiring layer 130a and the first semiconductor devices of the first device unit 120 and extends in a vertical direction (y direction). For convenience, only a portion of the first wiring structure 130 is indicated by reference numerals. The wiring layer 130a and the contact plug 130b may include, for example, a conductive material such as aluminum copper, copper, tungsten, other metals, or a combination thereof. According to an embodiment, the wiring layer 130a and the contact plug 130b may include a metal layer and a conductive barrier layer surrounding a surface of the metal layer. For example, the metal layer may include copper, tungsten, tantalum, titanium, cobalt, manganese, aluminum, or a combination thereof, and the conductive barrier layer may include tantalum, titanium, tantalum nitride, titanium nitride, aluminum nitride, tungsten nitride, or a combination thereof. Meanwhile, the number of stacked wiring layers 130a sequentially stacked in the vertical direction (y direction) in the first wiring structure 130 is not particularly limited and may vary.

The first dielectric layer 140 may include at least one of an insulating material, for example, silicon oxide, silicon nitride, silicon oxynitride, and a low-k material having a dielectric constant less than that of silicon oxide, but is not limited thereto. The first dielectric layer 140 may include a metal oxide such as aluminum oxide or hafnium oxide, or metal oxynitride. The first dielectric layer 140 may also be referred to as an interlayer insulating film or a metal interlayer insulating film. In addition, in FIGS. 1 and 2, for convenience, the first dielectric layer 140 is illustrated as a single layer, but is not limited thereto, and may be composed of multiple layers.

The third structure S3 may include a second device unit 150, a second wiring structure 160 for electrically connecting second semiconductor devices of the second device unit 150 to each other and/or the second semiconductor devices and the first semiconductor devices of the first device unit 120, and a second dielectric layer 170 for covering the second device unit 150 and insulating the second wiring structure 160.

The second device unit 150 may be on the first dielectric layer 140.

Similar to the first semiconductor devices of the first device unit 120, the second device unit 150 may also include a plurality of second semiconductor devices such as a transistor, a memory cell, a pixel sensor, other types of semiconductor devices, or a combination thereof.

However, the second semiconductor devices of the second device unit 150 may be manufactured at a low temperature, for example, at a temperature of about 450° C. or less without damaging the first and second structures S1 and S2, and may include a material having higher charge mobility than that of the first semiconductor devices.

To this end, according to the inventive concept, the second semiconductor devices may include a seed layer and a semiconductor layer crystallized on the seed layer.

The seed layer may be a layer that directly or indirectly helps improve the crystallinity of the semiconductor layer in preparation for growing the semiconductor layer on the first dielectric layer 140 having an amorphous characteristic. For example, the seed layer may determine a crystal direction of the semiconductor layer and help the semiconductor layer grow in the determined crystal direction, but is not limited thereto. The seed layer may assist the semiconductor layer to self-determine a crystal direction and grow without applying any force to the semiconductor layer.

The seed layer may include a two-dimensional (2D) semiconductor material, for example, at least one of a metal chalcogenide-based material, a carbon-containing material, and an oxide semiconductor material.

The metal chalcogenide-based material may be a transition metal dichalcogenide (TMDC) material including a transition metal and a chalcogen material. The transition metal may be at least one of Mo, W, Nb, V, Ta, Ti, Zr, Hf, Tc, and Re, and the chalcogen material may be at least one of S, Se, and Te.

The metal chalcogenide-based material may include a metal chalcogenide material including a non-transition metal, and the non-transition metal may include, for example, Ga, In, Sn, Ge, or Pb.

The carbon-containing material may be a carbon-containing material such as graphene, and when the seed layer includes graphene, at least one graphene may be included.

The oxide semiconductor material may be a material including a Ga oxide semiconductor, a Zn oxide semiconductor, or an In oxide semiconductor.

The semiconductor layer may include, for example, germanium (Ge). According to an embodiment, Ge be single crystal Ge having crystal orientation of (110) or (111).

In addition, the semiconductor layer may include a group IV compound semiconductor material such as SiGe or GeSn, a chalcogen material such as S, Se, or Te, or a combination thereof, but is not limited thereto.

In addition, the semiconductor layer may be doped with P-type or N-type impurities.

Describing an embodiment of the second device unit 150 shown in FIG. 2 in more detail, the second device unit 150 may include the CMOS device having Ge as a channel material and formed such that a PMOS transistor 151 and an NMOS transistor 153 operate complementarily on the first dielectric layer 140.

The PMOS transistor 151 may include a 2D semiconductor material seed layer 151a on the first dielectric layer 140, a P-type Ge layer 151b on the 2D semiconductor material seed layer 151a, a source/drain 151c on the P-type Ge layer 151b, a gate dielectric layer 151d on a channel area between source/drain areas 151c, and a gate electrode 151e on the gate dielectric layer 151d. The NMOS transistor 153 may have a configuration corresponding to that of the PMOS transistor 151.

FIG. 2 illustrates an embodiment in which the PMOS transistor 151 and the NMOS transistor 153 constituting the CMOS device have planar channels, but the present disclosure is not limited thereto. At least one of the PMOS transistor 151 and the NMOS transistor 153 may have a recessed channel.

Similar to the first wiring structure 130, the second wiring structure 160 may include a wiring layer 160a, and a contact plug 160b connecting the wiring layer 160a to the second semiconductor devices of the second device unit 150. The second wiring structure 160 may further include a through via 160c penetrating the first and second dielectric layers 140 and 170 in the vertical direction (y direction) to electrically connect the wiring layer 160a to the wiring layer 130b of the first wiring structure 130. For convenience, only a portion of the second wiring structure 160 is indicated by reference numerals, and materials and structures constituting the wiring layer 160a, the contact plug 160b, and the through via 160c may be similar to materials and structures exemplified while describing the wiring layer 130a and the contact plug 130b.

Similar to the first dielectric layer 140, the second dielectric layer 170 may also include an insulating material, for example, at least one of silicon oxide, silicon nitride, silicon oxynitride, a low-k material, metal oxide, or metal oxynitride. In addition, for convenience, the second dielectric layer 170 is also illustrated as a single layer in FIGS. 1 and 2, but is not limited thereto, and may be composed of multiple layers.

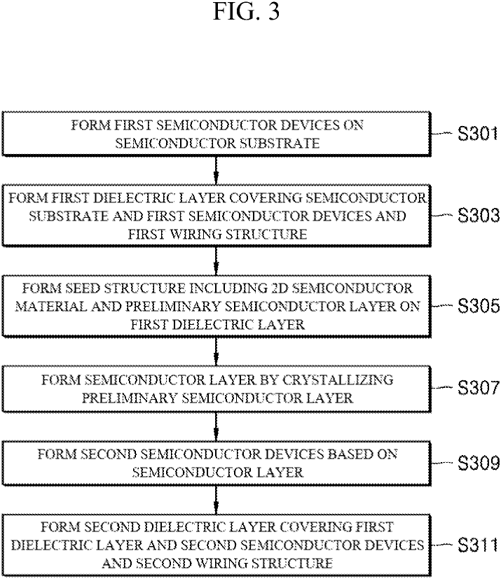

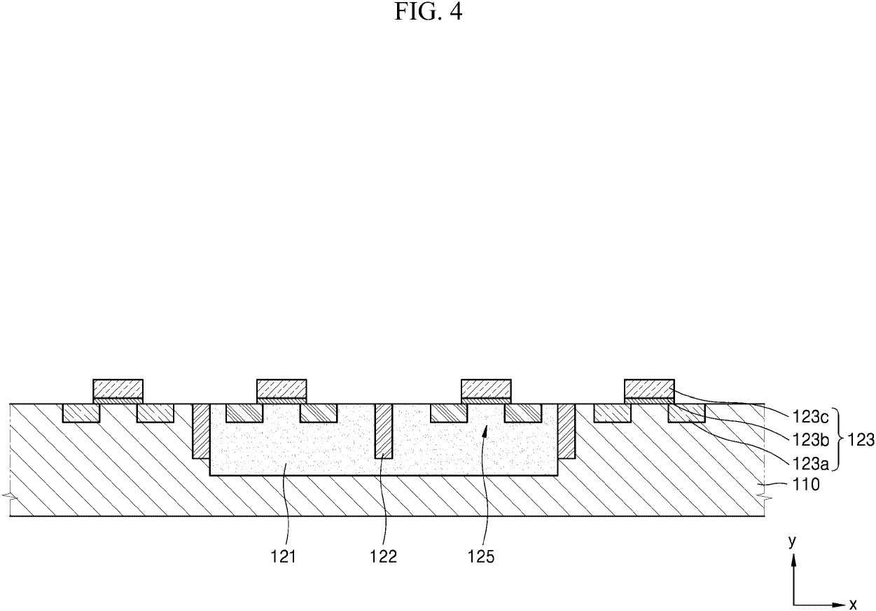

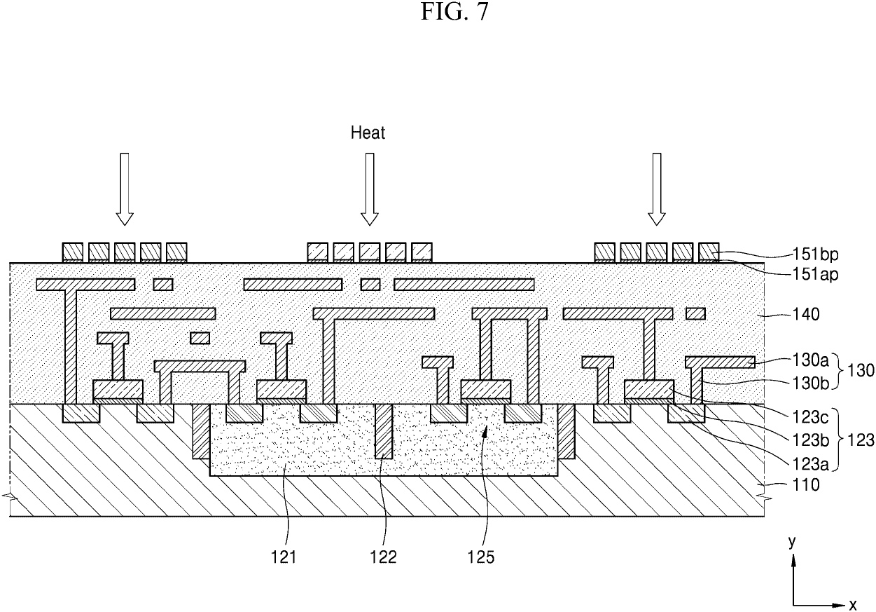

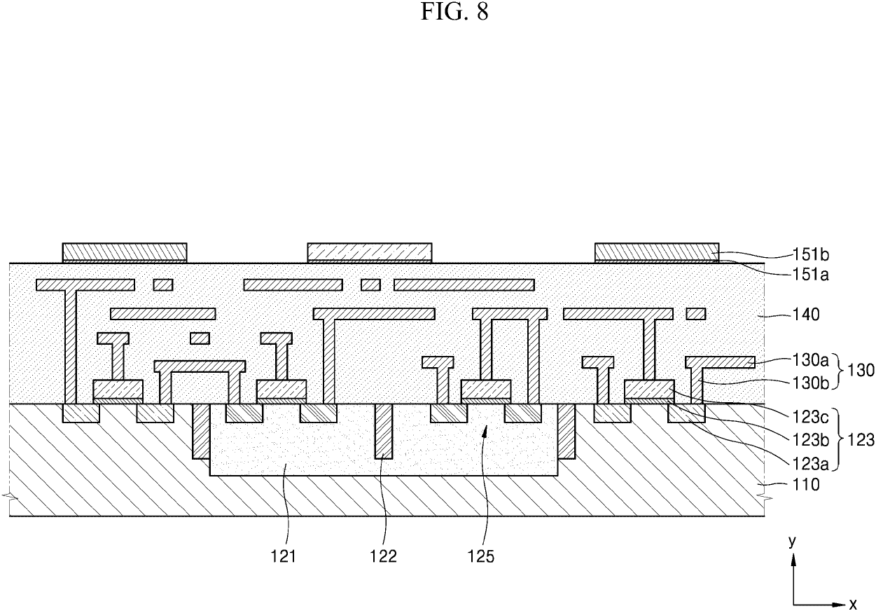

FIGS. 3 and 4 to 10 are views for explaining a method of manufacturing a monolithic 3D integrated circuit according to an exemplary embodiment of the present disclosure. FIGS. 4 to 10 show cross-sectional views in order of manufacturing processes according to an embodiment from among various manufacturing processes of the monolithic 3D integrated circuit 10 shown in FIGS. 1 and 2. In FIGS. 3 and 4 to 10, the same or corresponding reference numerals as in FIGS. 1 and 2 denote the same elements, and descriptions thereof will not be given herein for simplicity.

First, referring to FIGS. 3 and 4, in operation S301, first semiconductor devices are formed on the semiconductor substrate 110. The semiconductor substrate 110 may be a P-type silicon substrate, and the first semiconductor devices may be the NMOS transistor 123 and the PMOS transistor 125 constituting a CMOS device.

In some embodiments, a process of forming the first semiconductor devices may include forming the N-type well 121 by implanting N-type impurities into the entire surface of the semiconductor substrate 110, forming a plurality of device isolation layers 122 in the N-type well 121, forming a dielectric layer covering the semiconductor substrate 110, and subsequently forming a conductive layer covering the dielectric layer. In addition, in some embodiments, this process may include forming a gate dielectric layer (see 123b) and a gate electrode (see 123c) stacked on the semiconductor substrate 110 by selectively etching the dielectric layer and the conductive layer. In addition, in some embodiments, this process may include defining the source/drain area 123a by selectively implanting ions into the semiconductor substrate 110 on which the gate dielectric layer 123b and the gate electrode 123c are disposed. In addition, this process may include subsequently annealing the semiconductor substrate 110 to repair damage to a crystal lattice of the semiconductor substrate 110 caused by ion implantation. In some embodiments, annealing may be performed at a higher temperature than, for example, about 600° C., about 800° C., about 1000° C., or about 1200° C., and/or at a high temperature, for example, between about 600° C. to about 1200° C., about 800° C. to about 1000° C., about 750° C. to about 1200° C., or about 700° C. to about 1100° C.

An FEOL structure may be defined by performing operation S301 described above.

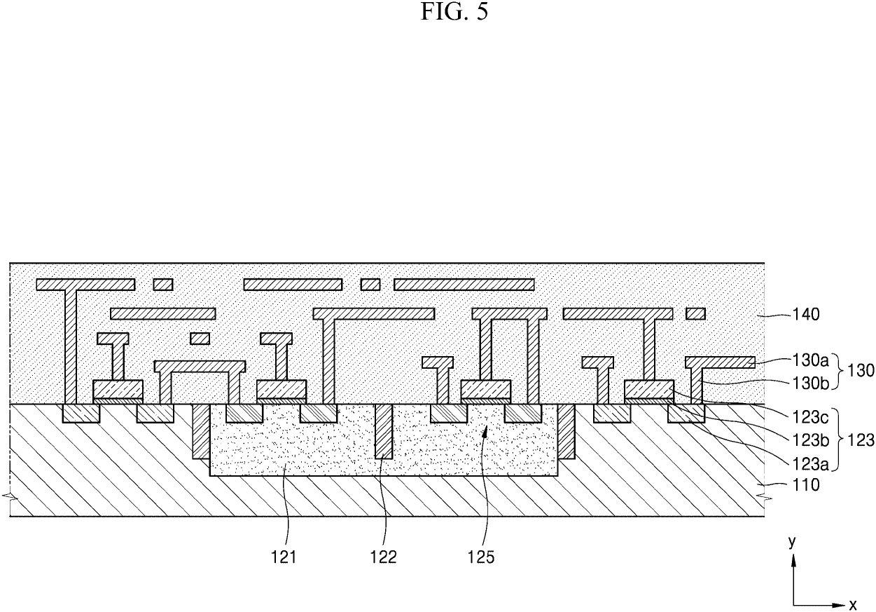

Referring to FIGS. 3 and 5, in operation S303, the first dielectric layer 140 covering the semiconductor substrate 110 and the first semiconductor devices and the first wiring structure 130 are formed.

In some embodiments, a process of forming the first dielectric layer 140 and the first wiring structure 130 may include repeatedly forming a sublayer on the semiconductor substrate 110, performing planarization on an upper surface or top surface of the sublayer, selectively etching the sublayer to form a horizontal opening and/or vertical opening, and forming the wiring layer 130a and the contact plug 130b by filling the horizontal opening and/or the vertical opening with a conductive material. Planarization may be performed, for example, by chemical mechanical polishing (CMP), and etching may be performed, for example, using photolithography.

A BEOL structure may be defined by performing operation S303 described above.

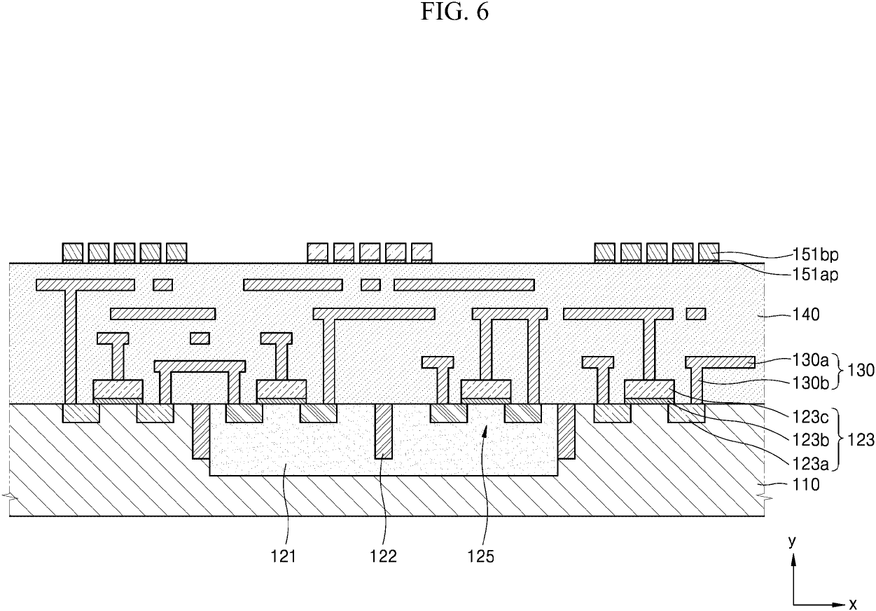

Referring to FIGS. 3 and 6, in operation S305, a seed structure 151ap including a 2D semiconductor material and a preliminary semiconductor layer 151bp are formed on the first dielectric layer 140. The seed structure 151ap and the preliminary semiconductor layer 151bp may be formed on an area where a second semiconductor device to be described later is formed. For convenience, reference numerals are indicated with the PMOS transistor 151 as the center.

The seed structure 151ap may include a plurality of island-like structures, and the preliminary semiconductor layer 151bp may also have a shape corresponding to the seed structure 151ap.

In some embodiments, a process of forming the seed structure 151ap and the preliminary semiconductor layer 151bp may include forming a 2D semiconductor material layer directly on the first dielectric layer 140 or forming a 2D semiconductor material layer on a separate growth substrate (or carrier substrate) and then transferring the 2D semiconductor material layer onto the first dielectric layer 140 through a mechanical or chemical exfoliation process, forming a 2D semiconductor material layer into the seed structure 151ap having a plurality of island-like structures through the exfoliation process or patterning, and forming the preliminary semiconductor layer 151bp including, for example, Ge, on the seed structure 151ap. The formation of the 2D semiconductor material layer and the preliminary semiconductor layer 151bp may be performed using a metal organic chemical vapor deposition (MOCVD) process, a molecular beam epitaxy (MBE) process, a chemical beam epitaxy (CBE) process, a hydride vapor phase epitaxy (HVPE) process, an ALD process, or the like.

Referring to FIGS. 3, 7 and 8, in operation S307, a semiconductor layer 151b is formed by crystallizing the preliminary semiconductor layer 151bp on the seed structure 151ap. For convenience, reference numerals are indicated with the PMOS transistor 151 as the center.

In some embodiments, a process of forming the semiconductor layer 151b may include forming the semiconductor layer 151b including single crystal Ge by applying heat to the seed structure 151ap and the preliminary semiconductor layer 151bp to maximize crystal grains of the preliminary semiconductor layer 151bp. The heat treatment process may be performed at a low temperature of, for example, about 450° C. or less. When the heat treatment process described above is performed, a seed layer 151a may be formed by combining the plurality of island-like structures constituting the seed structure 151ap.

Unlike the embodiments shown in FIGS. 6 to 8, according to the inventive concept, the seed structure 151ap and the preliminary semiconductor layer 151bp may have a film shape.

In this case, a process of forming the seed layer 151a and the semiconductor layer 151b may include forming the seed structure 151ap by forming a 2D semiconductor material layer on the first dielectric layer 140 (or forming a 2D semiconductor material layer on a separate growth substrate and then transferring the 2D semiconductor material layer as described above) to cover an upper surface of the first dielectric layer 140, forming the preliminary semiconductor layer 151bp including Ge to cover an upper surface of the seed structure 151ap at a low temperature of about 450° C. or less, and forming the seed layer 151a and the semiconductor layer 151b by selectively removing the seed structure 151ap and the preliminary semiconductor layer 151bp in an area other than an area for forming a second semiconductor device described later. According to an embodiment, the process of forming the seed layer 151a and the semiconductor layer 151b may include annealing the semiconductor layer 151b at a low temperature of about 450° C. or less after forming the semiconductor layer 151b to improve crystallinity.

According to the inventive concept, in manufacturing the monolithic 3D integrated circuit 10, in a low-temperature environment in which characteristics and reliability of lower silicon-based first semiconductor devices and/or the first wiring structure 130 are not deteriorated, a semiconductor layer including a semiconductor material having higher charge mobility than that of silicon, for example, Ge, may be formed on the first dielectric layer 140 of the BEOL structure. Accordingly, it is possible to overcome the integration limit of the existing monolithic technology and to ensure high performance and energy efficiency.

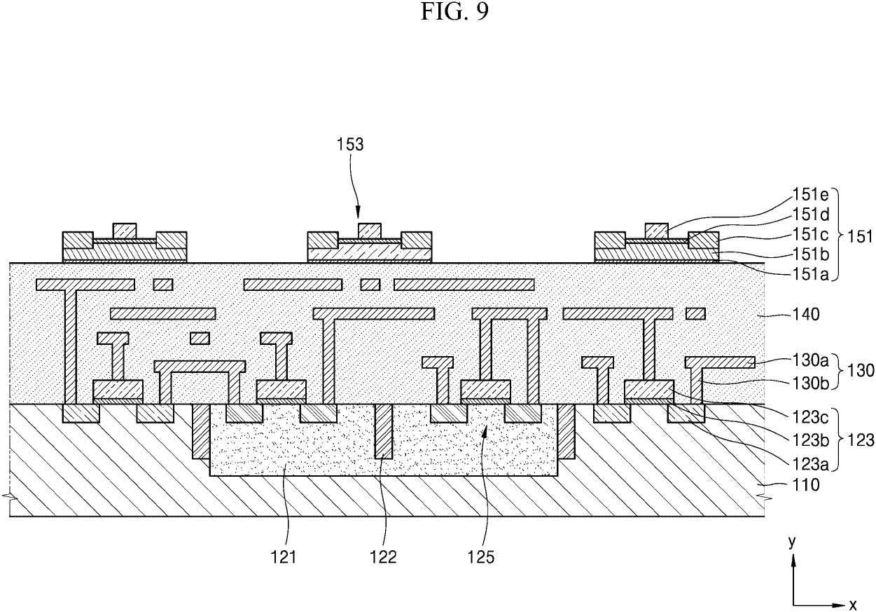

Referring to FIGS. 3 and 9, in operation S309, second semiconductor devices are formed based on the semiconductor layer 151b. The second semiconductor devices may be the PMOS transistor 151 and the NMOS transistor 153 constituting the CMOS device. For convenience, reference numerals are indicated with the PMOS transistor 151 as the center.

In some embodiments, a process of forming the second semiconductor devices may include forming the source/drain area 151c on the semiconductor layer 151b through patterning, forming the gate dielectric layer 151d on the channel area between the source/drain areas 151c, and forming the gate electrode 151e on the gate dielectric layer 151d through patterning.

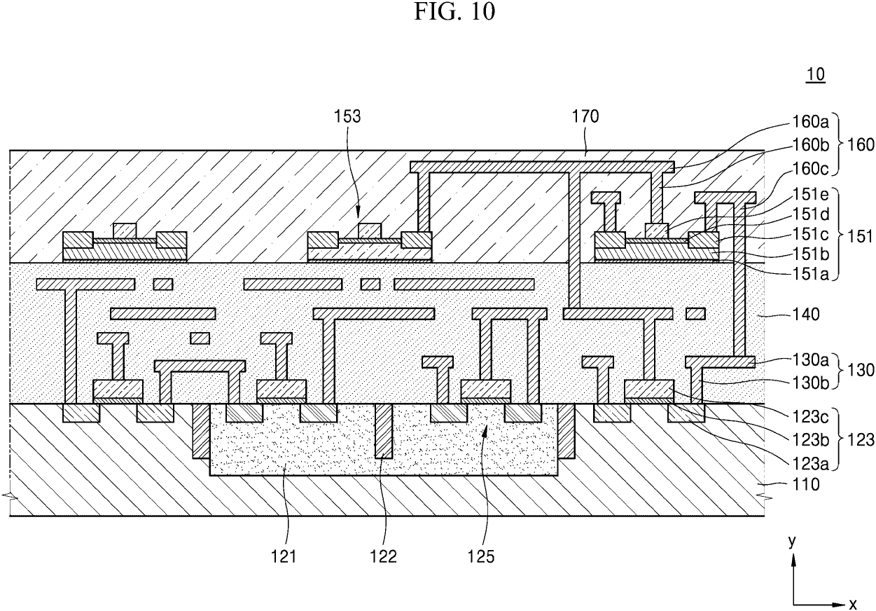

Referring to FIGS. 3 and 10, in operation S310, the second dielectric layer 170 covering the first dielectric layer 140 and the second semiconductor devices and the second wiring structure 160 are formed.

Because a process of forming the second dielectric layer 170 and the second wiring structure 160 is similar to the process of forming the first dielectric layer 140 and the first wiring structure 130 of operation S303 described with reference to FIGS. 3 and 5, the detailed description thereof will not be given herein.

While the present disclosure has been particularly shown and described with reference to embodiments thereof, it should not be construed as being limited to the descriptions set forth herein.

In addition, it will be apparent to one of ordinary skill in the art that various changes and modifications are possible within a range that does not deviate from the basic principles of the present disclosure.

1. A monolithic three-dimensional (3D) integrated circuit comprising:
a semiconductor substrate;
a first semiconductor device formed on the semiconductor substrate;
a dielectric layer configured to cover the semiconductor substrate and the first semiconductor device;
a wiring structure formed in the dielectric layer; and
a second semiconductor device formed on the dielectric layer and including a seed layer including a two-dimensional (2D) semiconductor material and a crystallized semiconductor layer on the seed layer.

2. The monolithic 3D integrated circuit of claim 1, wherein the 2D semiconductor material includes at least one of a metal chalcogenide-based material, a carbon-containing material, and an oxide semiconductor material.

3. The monolithic 3D integrated circuit of claim 1, wherein the semiconductor layer includes a semiconductor material having higher charge mobility than that of a semiconductor material constituting the semiconductor substrate.

4. The monolithic 3D integrated circuit of claim 1, wherein the semiconductor layer includes at least one of germanium, a compound semiconductor material containing the germanium, and a chalcogen material.

5. The monolithic 3D integrated circuit of claim 1, wherein the semiconductor substrate includes silicon.

6. A method of manufacturing a monolithic 3D integrated circuit, the method comprising:
forming a first semiconductor device on a semiconductor substrate;
forming a dielectric layer covering the semiconductor substrate and the first semiconductor device and a wiring structure in the dielectric layer;
forming a seed structure including a 2D semiconductor material on the dielectric layer; and
forming a crystallized semiconductor layer on the seed structure.

7. The method of claim 6, wherein the forming of the seed structure comprises:
transferring the seed structure formed on the growth substrate onto the dielectric layer or directly forming the seed structure on the dielectric layer.

8. The method of claim 6, wherein the seed structure includes a plurality of islandlike structures including the 2D semiconductor material or has a film shape including the 2D semiconductor material.

9. The method of claim 6, wherein the 2D semiconductor material includes at least one of a metal chalcogenide-based material, a carbon-containing material, and an oxide semiconductor material.

10. The method of claim 6, wherein the crystallized semiconductor layer includes a semiconductor material having higher charge mobility than that of a semiconductor material constituting the semiconductor substrate.

11. The method of claim 6, wherein the crystallized semiconductor layer includes at least one of germanium, a compound semiconductor material containing the germanium, and a chalcogen material.

12. The method of claim 6, wherein the forming of the crystallized semiconductor layer is performed through heat treatment at a temperature of 450° C. or less.

13. The method of claim 6, wherein the semiconductor substrate includes silicon.
